(19) United States
(12) Patent Application Publication
(10) Pub. No.: US 2022/0068879 A1
(43) Pub. Date: Mar. 3, 2022

(54) SEMICONDUCTOR DEVICE

(71) Applicant: KIOXIA CORPORATION, Tokyo (JP)

(72) Inventor: Yuichi SANO, Setagaya Tokyo (JP)

(21) Appl. No.: 17/189,132

(22) Filed: Mar. 1, 2021

(30) Foreign Application Priority Data
Aug. 28, 2020 (JP) 2020-144745

(51) Int. Cl. H01L 25/065

(52) U.S. Cl. CPC H01L 25/0652; H01L 2225/06506; H01L 2225/06586; H01L 2225/06562; H01L 2225/0651

(57) ABSTRACT

According to one embodiment, a semiconductor device includes a substrate with a first terminal, a first semiconductor memory chip on the substrate and having a first pad, and a second semiconductor memory chip on the first semiconductor memory chip and having a second pad. A first bonding wire connects to the first terminal and both the first pad and the second pad. A second bonding wire connects to the first terminal and one of the first pad or the second pad from a coordinate position offset from a coordinate position of the first bonding wire.

### CROSS-REFERENCE TO RELATED APPLICATION

This application is based upon and claims the benefit of priority from Japanese Patent Application No. 2020-144745, filed Aug. 28, 2020, the entire contents of which are incorporated herein by reference.

### FIELD

Embodiments of the present disclosure relate to a semiconductor device.

### BACKGROUND

In a packaged semiconductor device in which NAND flash memory chips are stacked, there is a method in which inductance is reduced and operations are stabilized by running signal wiring and power supply wiring in parallel. The power supply can be enhanced to stabilize the operations.

### BRIEF DESCRIPTION OF THE DRAWINGS

FIG. 1 is a schematic cross-sectional view of a semiconductor device according to an embodiment.

FIG. 2 is a top view of a semiconductor device according to an embodiment.

FIG. 3 is a top view of a semiconductor device according to an embodiment.

FIG. 4 is a schematic cross-sectional view of a semiconductor device according to an embodiment.

FIG. 5 is a top view of a semiconductor device according to an embodiment.

FIG. 6 is a schematic cross-sectional view of a semiconductor device according to an embodiment.

FIG. 7 is a schematic cross-sectional view of a semiconductor device according to an embodiment.

FIG. 8 is a top view of a semiconductor device according to an embodiment.

FIG. 9 is a top view of a semiconductor device according to an embodiment.

### DETAILED DESCRIPTION

Embodiments provide a semiconductor device having improved electrical characteristics.

In general, according to one embodiment, a semiconductor device includes a substrate having a first terminal. A first semiconductor memory chip is on the substrate and has a first pad. A second semiconductor memory chip is on the first semiconductor memory chip and has a second pad. A first bonding wire connects to the first terminal and both the first pad and the second pad. A second bonding wire connects to the first terminal and one of the first pad or the second pad from a coordinate position offset from a coordinate position of the first bonding wire.

Hereinafter, certain example embodiments will be described with reference to the drawings.

In the present specification, some elements are given multiple names. The these names are merely examples, and it does not mean that such elements cannot be referred to by other names. In addition, elements to which to which example descriptions or characteristics are provided in the context of a particular example embodiment are not limited to such example descriptions and/or characteristics in the context of different embodiments.

In addition, the drawings are schematic, and the depicted relationships between the thicknesses and the plane dimensions and the ratios of the thicknesses of each layer may differ from the actual ones. In addition, there may be cases where the dimensional relationships or the dimensional ratios in the drawings are different from each other. In addition, some aspects can be omitted from certain the drawings for clarity in the depiction and description of other aspects.

### First Embodiment

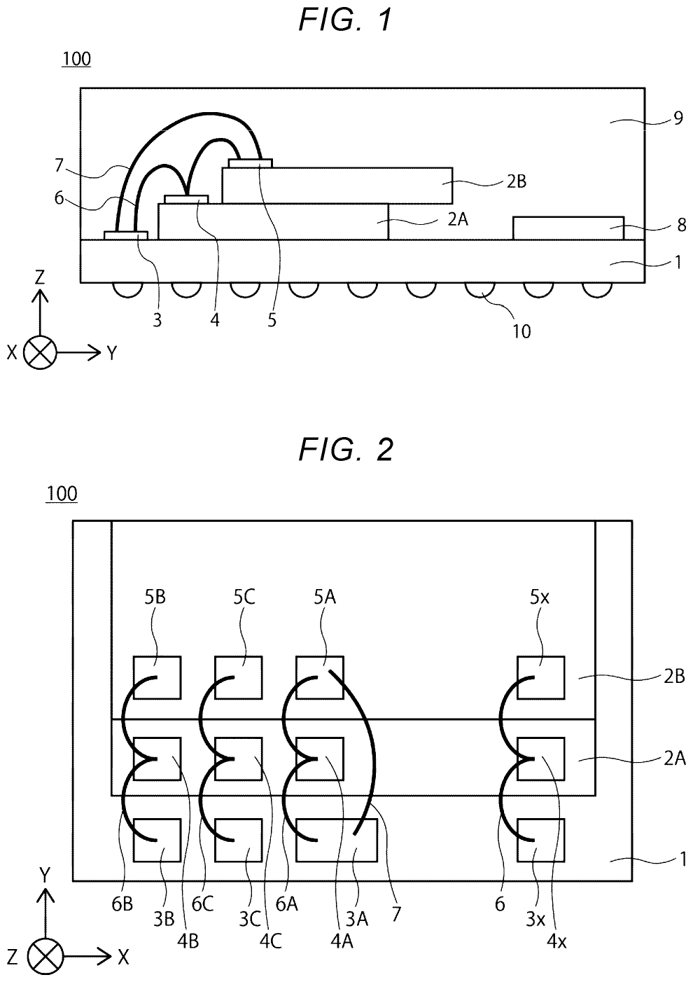

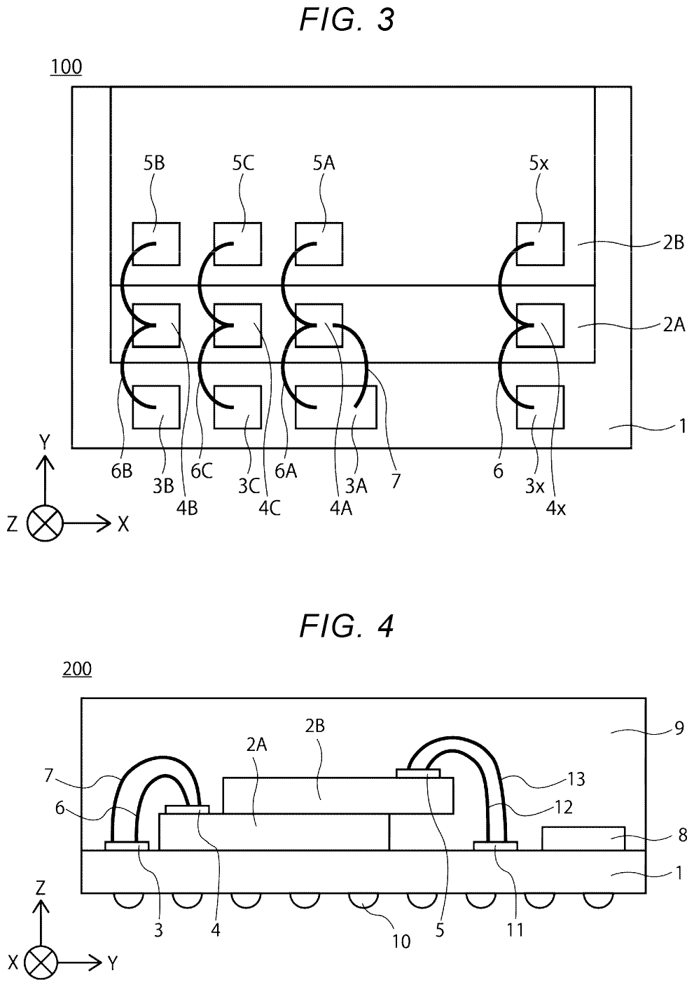

A first embodiment relates to a semiconductor device. A schematic cross-sectional view of a semiconductor device 100 is illustrated in FIG. 1. Top views of a main part of the semiconductor device 100 are illustrated in FIG. 2 and FIG. 3. More specifically, the semiconductor device 100 in the first embodiment is a packaged semiconductor device in which NAND flash memory chips or the like are mounted. In the drawings, a XYZ coordinate axis system is depicted for purposes of explanation, but such an axis system is not a limitation and is utilized for the purpose of describing relative positional relationships amongst the depicted aspects.

The semiconductor device 100 is an example of a storage device. The semiconductor device 100 includes a substrate 1 having semiconductor memory chips 2 (2A, 2B) mounted thereon. The semiconductor device 100 also includes a first bonding wire 6, a second bonding wire 7, a controller chip 8, a sealing material 9, and solder balls 10.

The substrate 1 is utilized as a supporting substrate for the semiconductor memory chip 2. Specifically, the substrate 1 is a multi-layer wiring substrate in this example. A semiconductor memory chip 2 is provided on a first surface side of the substrate 1. Hemispherical electrodes such as solder balls 10 for externally connecting the semiconductor device 100 are provided on a second surface side of the substrate 1 opposite the first surface side.

The substrate 1 is electrically connected to the semiconductor memory chip 2 via bonding wires. The substrate 1 includes terminals 3 connected to the semiconductor memory chips 2. The terminals 3 are of a plurality of different types such as power supply terminals, input/output (IO) terminals, ground terminals, and signal terminals other than the IO terminals, and each such terminal is provided on the first surface side of substrate 1. For example, an IO terminal is a terminal for data input/output of a semiconductor memory chip 2. For example, a signal terminal is a terminal for inputting control signals that are used for controlling the operations of a semiconductor memory chip 2. FIG. 2 illustrates an example of wiring between the substrate 1 and the semiconductor memory chips 2. FIG. 2 illustrates four terminals (3A, 3B, 3C, and 3x). There may be a plurality of additional terminals between the terminal 3A and the terminal 3x. In FIG. 2 and FIG. 3, a plurality of bonding wires are connected to the semiconductor memory chip 2A from the terminal 3A (terminal 3A will be referred to as “first terminal 3A”).

In FIG. 2 and FIG. 3, the first terminal 3A is a power supply terminal or a ground terminal. When the first terminal 3A is the power supply terminal, then the terminal 3B (referred to as “second terminal 3B”) is a ground terminal and a terminal 3C (referred to as “third terminal 3C”) is an IC terminal. The third terminal 3C is between the first terminal 3A and the second terminal 3B and is also adjacent to both of the first terminal 3A and the second terminal 3B.

When the first terminal 3A is a ground terminal, then the second terminal 3B is a power supply terminal and the third terminal 3C is again an IO terminal. Since a case in which the IO terminal is a differential wiring terminal is also an embodiment, there may be one or two IO terminals that are separately provided between the power supply terminal and the ground terminal. The voltage applied to the ground terminal is lower than the voltage applied to the power supply terminal.

A semiconductor memory chip 2 is provided on the substrate 1. Each semiconductor memory chip 2 is a semiconductor chip that reads and writes data. As a nonvolatile memory chip, a NAND memory chip, a phase-change memory chip, a resistance-change memory chip, a ferroelectric memory chip, a magnetic memory chip, or the like may be used. As a volatile memory chip, a dynamic random access memory (DRAM) or the like may be used. It is preferable that the semiconductor memory chips 2 are semiconductor chips having the same circuit design and the same structure except the individual differences associated with collective functioning of such chips. In addition, in the present embodiment, a nonvolatile memory chip or a volatile memory chip may be used as the semiconductor memory chip 2. The number of the semiconductor memory chips 2 is not limited to two, but may be three or more; however, from a viewpoint of enhancing the power supply for high-speed operation, it may be preferable that the number of stacked stages (that is, the number of semiconductor memory chips 2 connected by the first bonding wire 6A) is two as illustrated in FIG. 1.

As illustrated in FIG. 1, when a plurality of semiconductor memory chips 2 are provided, it is preferable that the semiconductor memory chips 2 are shifted in the Y-direction with respect to one another. When a plurality of semiconductor memory chips 2 are provided, for example, as illustrated in FIG. 1, the first semiconductor memory chip 2A is provided on the substrate 1, and the second semiconductor memory chip 2B is provided on the first semiconductor memory chip 2A.

It is preferable that a space between the semiconductor memory chips 2, or between the semiconductor memory chip 2A and the substrate 1 is filled with an adhesive resin film or the like.

Each semiconductor memory chip 2 includes pads as terminals for being connected to the substrate 1 or being connected to another semiconductor memory chip 2. The pads can be a plurality of types of pads such as a power supply pad, an IO pad, a ground pad, and a signal pad other than the IO. Each pad is provided on the upper surface of a semiconductor memory chip 2 and is connected to internal wirings of the semiconductor memory chip 2. FIG. 2 and FIG. 3 illustrates examples of wirings between the substrate 1 and the semiconductor memory chips 2. In FIG. 2 and FIG. 3, four pads 4 (4A, 4B, 4C, and 4x) of the first semiconductor memory chip 2A are illustrated. In addition, in FIG. 2 and FIG. 3, four pads 5 (5A, 5B, 5C, and 5x) of the second semiconductor memory chip 2B are illustrated. There may be a plurality of additional pads between the pad 4A and the pad 4x and between the pad 5A and the pad 5x. In FIG. 2 and FIG. 3, the first terminal 3A of the substrate 1, and the first pad 4A of the first semiconductor memory chip 2A and the second pad 5A of the second semiconductor memory chip 2B are electrically connected via two bonding wires 6 (6A) and 7.

The first pad 4A is connected to a first internal wiring of the first semiconductor memory chip 2A, and the second pad 5A is connected to a second internal wiring of the second semiconductor memory chip 2B. Both the first internal wiring and the internal second wiring are either the power supply wiring or the ground wiring. That is, both the first pad 4A and the second pad 5A are both either a power supply pad or a ground pad.

The first semiconductor memory chip 2A and the second semiconductor memory chip 2B have memory circuit designs in common with each other, and since the first pad 4A of the first semiconductor memory chip 2A corresponds to the second pad 5A of the second semiconductor memory chip 2B, it is possible to enhance the wirings of the power supply circuits common to a plurality of semiconductor memory chips 2. From a viewpoint of enhancing the power supply, it is preferable to use a second bonding wire 7 for both the pad on the power supply side and the pad on the ground side on either side of the pad(s) of the IO wiring. The IO wiring is a wiring for inputting and outputting data, and may be a signal wiring. However, since it is necessary to increase the area of the first terminal 3A in order to form a second bonding wire 7, by using the second bonding wire 7 at just the pad on the power supply side, it is possible to enhance the power supply for operating the semiconductor memory chips 2 efficiently and effectively.

A fourth pad 4C is positioned adjacent and between to the first pad 4A and the third pad 4B. The third pad 4B is connected to a third internal wiring of the first semiconductor memory chip 2A. The fourth pad 4C is connected to a fourth internal wiring of the first semiconductor memory chip 2A. For example, one of the first internal wirings and the third wiring is the power supply wiring and the other is the ground wiring, and the fourth internal wiring is the IO wiring. When the first pad 4A and the second pad 5A are the power supply pads, the third pad 4B and the pad 5B are the ground pads, and the fourth pad 4C and the pad 5C are the IO pads. In the present example, the first pad 4A is connected to the power supply wiring of the first semiconductor memory chip 2A, the third pad 4B is connected to the ground wiring of the first semiconductor memory chip 2A, and the fourth pad 4C is connected to the IO wiring of the first semiconductor memory chip 2A. The second pad 5A is connected to the power supply wiring of the second semiconductor memory chip 2B, the pad 5B is connected to the ground wiring of the second semiconductor memory chip 2B, and the pad 5C is connected to the IO wiring of the second semiconductor memory chip 2B. If the first pad 4A and the second pad 5A are instead the ground pads, then the third pad 4B is the power supply pad, and the fourth pad 4C is the IO pad. Thus, the first pad 4A would be connected to the ground wiring of the first semiconductor memory chip 2A, the third pad 4B would be connected to the power supply wiring of the first semiconductor memory chip 2A, and the fourth pad 4C would be connected to the IO wiring of the first semiconductor memory chip 2A. Similarly, the second pad 5A would be connected to the ground wiring of the second semiconductor memory chip 2B, the pad 5B would be connected to the power supply wiring of the second semiconductor memory chip 2B, and the pad 5C would be connected to the IO wiring of the second semiconductor memory chip 2B. Since a case where the IO pad is a differential wiring pad is also provided as embodiment, one or two IO pads can be provided between the power supply pad and the ground pad on each semiconductor memory chip 2, and similarly for the terminals 3 on the substrate 1 as well.

The terminals 3 on the substrate 1 and the pads 4 and 5 of the semiconductor memory chip 2 are electrically connected to each other by bonding wires. The bonding wires 6 connects the substrate 1 terminals 3 to pads (4, 5) on both the first semiconductor memory chip 2A and the second semiconductor memory chip 2B. The first bonding wire 6A connects the first terminal 3A to the first pad 4A. The second bonding wire 7 connects the first terminal 3A 1 to the first pad 4A on the first semiconductor memory chip 2A or, alternatively, to the second pad 5A on the second semiconductor memory chip 2B.

In FIG. 2 and FIG. 3, the first terminal 3A of the substrate 1, the first pad 4A of the first semiconductor memory chip 2A, and the second pad 5A of the second semiconductor memory chip 2B are connected to each other via the first bonding wire 6A. A third bonding wire 6B connects the terminal 3B of substrate 1 to the pad 4B of the first semiconductor memory chip 2A. The fourth bonding wire 6C connects the terminal 3C of the substrate 1 to the pad 4C of the first semiconductor memory chip 2A.

In FIG. 2 and FIG. 3, the terminal 3B of the substrate 1, the pad 4B of the first semiconductor memory chip 2A, and the pad 5B of the second semiconductor memory chip 2B are connected to each other via the third bonding wire 6B.

In FIG. 2 and FIG. 3, the terminal 3C of the substrate 1, the pad 4C of the first semiconductor memory chip 2A, and the pad 5C of the second semiconductor memory chip 2B are connected to each other via the fourth bonding wire 6C.

In FIG. 2, the terminal 3A of the substrate 1 and the pad 5A of the second semiconductor memory chip 2B are directly connected to each other by the second bonding wire 7.

In FIG. 3, the first terminal 3A of the substrate 1 and the first pad 4A of the first semiconductor memory chip 2A are directly connected to each other by the second bonding wire 7. That is, the second bonding wire 7 spans over the first semiconductor memory chip 2A without contacting the pad 4A thereon. This is in contrast to the bonding wires 6 which connect to from one semiconductor chip 2 to the next in connective stages such that a portion of each bonding wire 6 directly contacts a pad on each of the first semiconductor chip 2A and second semiconductor chip 2B.

In a similar manner to the above terminals and pads, the terminal 3x of the substrate 1, the pad 4x of the first semiconductor memory chip 2A, and the pad 5x of the second semiconductor memory chip 2B are connected to each other via a bonding wire 6x.

The second bonding wire 7 connects the first terminal 3A to the pad 4A (or to the pad 5A) from a coordinate position on the first terminal 3A, which is different from the coordinate position of the first bonding wire 6A. That is, the first bonding wire 6A and the second bonding wire 7 are a physically connected to the first terminal 3A at positions that are offset (non-overlapping in plan view) from each other. Additionally, the second bonding wire 7 is a wiring that does not physically connect the semiconductor memory chips 2 to each other. The second bonding wire 7 runs generally in parallel with the first bonding wire 6A, and is connected to one of the first pad 4A or the second pad 5A, but not directly to both. The second bonding wire 7 extends toward the semiconductor memory chips 2 from the first terminal 3A as a start point, which is the same start point as the first bonding wire 6A. However, since the first bonding wire 6A and the second bonding wire 7 do not overlap on the first terminal 3A (in plan view), the XY coordinates of the start point of the first bonding wire 6A and the XY coordinates of the start point of the second bonding wire 7 on the first terminal 3A are different from each other.

The first bonding wire 6A and the second bonding wire 7 extend from the first terminal 3A, which is a unitary terminal. If the first bonding wire 6A and the second bonding wire 7 are formed from two separate terminals, this is not preferable because the area occupied by such separate terminals on the substrate 1 generally increases. For example, if each separate terminal has an area that is approximately the same as that of other terminals, it can be difficult to form a plurality of bonding wires as necessary due to crowding of the terminals. In addition, if the area of the first terminal 3A is made too much larger than that of other terminals, a larger area on the substrate 1 is occupied by the terminals, which also affects the formation of other bonding wires.

From a viewpoint of enhancing the power supply by reducing the resistance and inductance caused by the bonding wire(s), it is desirable to use the first bonding wire 6A and the second bonding wire 7 as depicted in FIG. 2 or FIG. 3.

The influence on the operation of the semiconductor memory chip 2 due to the wiring resistance and inductance of the bonding wires increases when the operation speed of the semiconductor memory chip 2 is higher. For example, it may be preferable to adopt a configuration in which a combination of the first bonding wire 6A and the second bonding wire 7 as depicted in the first embodiment are used for a power supply pad or a ground pad next to a pad or pads connected to the IO wiring that operates at a high speed of 500 MHz or higher. Since the influence on the power supply becomes even greater when the operation speed is 1000 MHz or higher, it may be even more preferable to adopt a configuration in which a combination of the first bonding wire 6A and the second bonding wire 7 as depicted in the first embodiment are used for the power supply pad or the ground pad next to the pad connected to the IO wiring that requires such a high-speed operation.

Since the impedance tends to increase at the upper stage side (e.g., a higher chip in the stack) where the wiring becomes long when the semiconductor memory chips 2 are stacked in multiple stages, it may be preferable to connect the second bonding wire 7 to the upper stage side of the semiconductor memory chips 2 (e.g., the higher chip in the stack).

When the first bonding wire 6A and the second bonding wire 7 run in parallel for connection, the first bonding wire 6A and the second bonding wire 7 form a circuit loop. By such a circuit loop being formed, it is possible to enhance the power supply of the corresponding wirings of the first semiconductor memory chips 2A and the second semiconductor memory chips 2B.

It is preferable that the second bonding wire 7 is easily manufactured from a viewpoint of wiring space by connecting to the second semiconductor memory chips 2B on the upper stage side. Since the bonding wire 6 extending from the substrate 1 is formed on the pad 4 of the first semiconductor memory chip 2A on the lower stage side, and the bonding wire 6 extending to the second semiconductor memory chip 2B is formed, when the second bonding wire 7 is connected to the first semiconductor memory chip 2A which is at the lower stage side of the second semiconductor memory chip 2B, the reliability of the wire connection may decrease. Therefore, it is preferable that the second bonding wire 7 is connected to the second pad 5 of the second semiconductor memory chip 2B side on the upper stage side.

In addition, it may be preferable that the shape of the fourth bonding wire 6C be different from that of the adjacent first bonding wire 6A and the third bonding wire 6B, and it is preferable that the interference between the bonding wires decreases when the shapes of the bonding wires are made different from each other. To change the shape of the bonding wire, changing the bonding method may be used as an example. For example, when forming the fourth bonding wire 6C, the bonding wire can be formed by positive bonding, that is, the bonding wire is formed by forming a loop from the semiconductor memory chips 2 side toward the substrate 1 by ball bonding and stitch bonding, and when forming the adjacent first bonding wire 6A and the third bonding wire 6B, the bonding wire can be formed by reverse bonding, that is, the bonding wire is formed by forming a loop from the substrate 1 toward the semiconductor memory chips 2 side via bumps. In the case of positive bonding, the balls remain on the chip side and the stitch marks remain on the substrate side. In the case of reverse bonding, the balls remain on the substrate side, and stitch marks remain on the bumps on the semiconductor chip side. The shape of the adjacent bonding wires 6 can also be changed by intentionally changing the height of the bonding wire. Since the wiring resistance and inductance tend to increase when the length of the bonding wire increases, it is preferable to change the shape of the bonding wire such that the height of the bonding wire does not become too high. In addition, in the bonding wires 6 and 7 in the first embodiment, bonding wires having bumps may be adopted, or a wire having no break on the chain by wedge bonding may be adopted.

The controller chip 8 is a semiconductor chip that controls reading/writing and erasing of the semiconductor memory chips 2. In some examples, the controller chip 8 may be provided above or below the stack of semiconductor memory chips 2 instead of at the position illustrated in FIG. 1. The controller chip 8 is similarly connected to the substrate 1 by wiring and electrically connected to the semiconductor memory chips 2. Such electrical connections may be made via internal wiring of the substrate 1 or otherwise.

If the bonding wire 6A is formed by reverse bonding, the bonding wire 7 may be formed by positive bonding. If the bonding wire 6A is formed by positive bonding, the bonding wire 7 may be formed by reverse bonding.

The location where the bonding wire reaches the maximum height differs between positive bonding and reverse bonding. The maximum height of the bonding wire formed by positive bonding is closer to the height of the chip than reverse bonding.

Sealing material 9 seals the semiconductor memory chip 2, the bonding wires 6 and 7, and the controller chip 8. The sealing material 9 is, for example, a molded resin.

The solder balls 10 are terminals that electrically connect the semiconductor device 100 to the outside.

### Second Embodiment

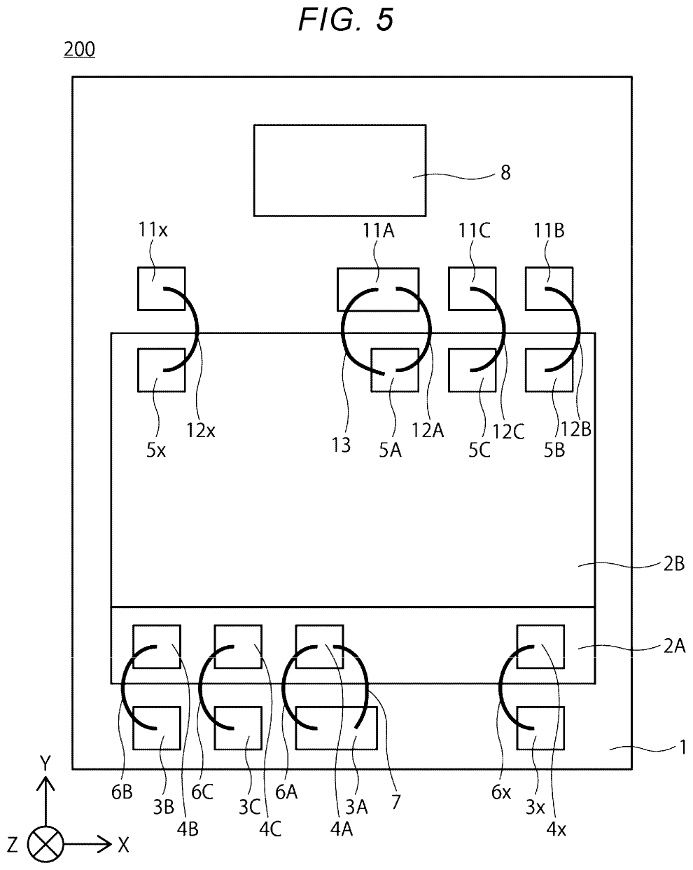

The second embodiment is a modification example of the semiconductor device 100 in the first embodiment. FIG. 4 illustrates a schematic cross-sectional view of a semiconductor device 200 in the second embodiment. FIG. 5 is a top view of a main part of the semiconductor device 200. The semiconductor device 200 is different from the semiconductor device 100 in that the second semiconductor memory chip 2B is provided on the first semiconductor memory chip 2A in reversed manner, such that the pads 4 of the first semiconductor memory chips 2A and the pads 5 of the second semiconductor memory chips 2B are on opposite sides from each other, thus connections from the different semiconductor memory chips 2 to the terminals on the substrate occur via bonding wires from different coordinate positions on the substrate 1. The description of the content common to the first embodiment and the second embodiment will not be repeated.

In the first embodiment, the first semiconductor memory chip 2A and the second semiconductor memory chip 2B are stacked in the same orientation while being shifted in the Y-direction, but in the second embodiment, the second semiconductor memory chip 2B is rotated from the first semiconductor memory chip 2A by 180° but also are stacked while being shifted in the Y-direction. Since the first semiconductor memory chip 2A and the second semiconductor memory chip 2B have common memory circuits and are preferably chips of the same circuit design, when the semiconductor memory chips 2 are arranged while being rotated by 180° as in the second embodiment, it is preferable to adopt a configuration in which the power supply is similarly enhanced for both the semiconductor memory chips 2.

Since the first semiconductor memory chip 2A and the second semiconductor memory chip 2B are provided in a reverse orientation, even if the bonding wires 6 were extended to the second semiconductor memory chip 2B, the first semiconductor memory chip 2A and the second semiconductor memory chip 2B cannot be easily electrically connected to the same bonding wires. Therefore, the substrate 1 and the second semiconductor memory chip 2B are connected to each other by the bonding wires 12 and 13 directly from the substrate 1 rather than via extended portions of the bonding wires 6.

In the first embodiment, the second bonding wire 7 can be directly connected to the second semiconductor memory chip 2B, but in the second embodiment, the second bonding wire 7 is connected to the first pad 4A of the first semiconductor memory chip 2A.

In addition to the terminals 3, terminals 11 (11A, 11B, 11C, 11D) are provided on the substrate 1. The terminals 11 are connected to the pads 5 of the second semiconductor memory chip 2B via the bonding wires 12 and 13. The terminals 11 are the similar to the terminals 3 excepting that the row position orientations are inverted (e.g., terminal 11x is on the left-hand side in FIG. 5 and terminal 3x is on the right-hand side in FIG. 5).

In FIG. 5, the terminal 11A of the substrate 1 and the pad 5A of the second semiconductor memory chip 2A are connected to each other via a fifth bonding wire 12A. In FIG. 5, the terminal 11B and the pad 5B are connected to each other via the bonding wire 12B. In FIG. 5, the terminal 11C and the pad 5C are connected to each other via the bonding wire 12C. In FIG. 5, the fourth terminal 11A and the second pad 5A are connected to each other via a sixth bonding wire 13. It is preferable that both the second bonding wire 7 and the sixth bonding wire 13 are provided to enhance the power supply of the circuit common to the first semiconductor memory chips 2A and the second semiconductor memory chips 2B.

### Third Embodiment

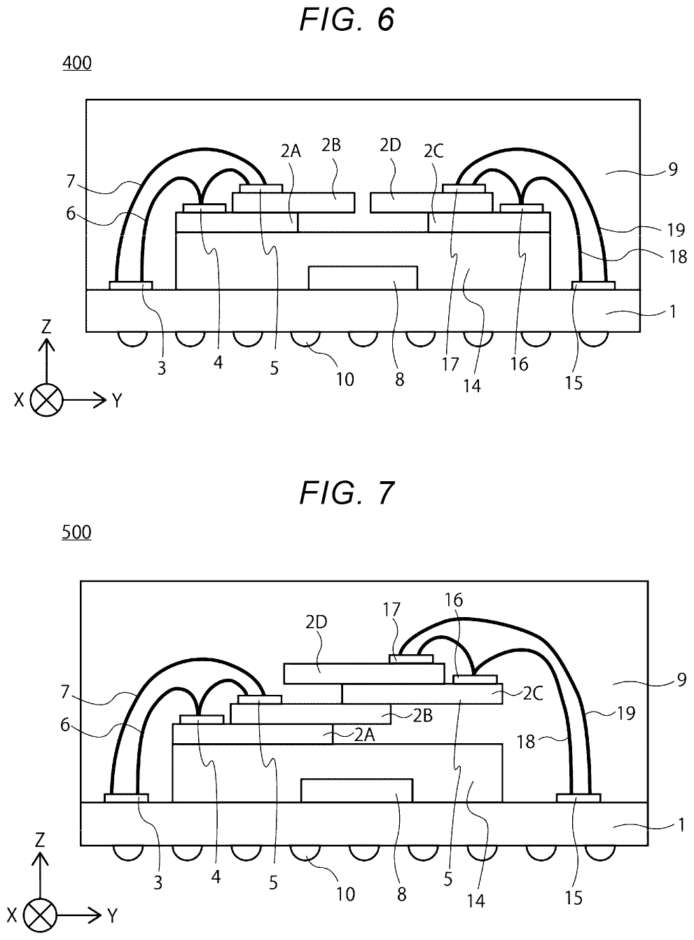

The third embodiment is a modification example of the semiconductor device 100 in the first embodiment. FIG. 6 illustrates a schematic cross-sectional view of a semiconductor device 300 in the third embodiment. The semiconductor device 300 is different from the semiconductor device 100 in point that a controller chip 8 is provided at a level below and at planar position between two stacked bodies in which two semiconductor memory chips 2 are stacked. The two different stacked bodies are above the controller chip 8 and face each other, though are they rotated by 180° from one another. The description of the content common to the first embodiment and the third embodiment will not be repeated.

In the third embodiment, the controller chip 8 is covered with an adhesive resin composition 14 such as DAF (die-attached film). The stacked body in which a third semiconductor memory chip 2C and a fourth semiconductor memory chip 2D are stacked is provided on the adhesive resin composition 14 so as to face the stacked body in which a first semiconductor memory chip 2A and a second semiconductor memory chip 2B are stacked (though rotated by 180°). The stacked body in which the first semiconductor memory chip 2A and the second semiconductor memory chip 2B are stacked and the stacked body in which the third semiconductor memory chip 2C and the fourth semiconductor memory chip 2D are stacked are the same except the being rotated by 180°.

Bonding wires 6 and 7 that are connected to the first semiconductor memory chip 2A and the second semiconductor memory chip 2B on the left side of FIG. 6 are formed on a terminal 3 of the substrate 1. A terminal 15 is provided on the substrate 1 at a side opposite to the terminal 3 side. Bonding wires 18 and 19 that are connected to a pad 16 of the third semiconductor memory chip 2C and a pad 19 of the fourth semiconductor memory chip 2D are provide from the terminal 15 of the substrate 1. The bonding wire 18 corresponds to the first bonding wire 6 in function. The bonding wire 19 corresponds to the second bonding wire 7 in function. The bonding wire 18 is connected to both the third semiconductor memory chip 2C and the fourth semiconductor memory chip 2D, and the bonding wire 19 is connected to a pad 17 of the fourth semiconductor memory chip 2D, which corresponds to the second pad 5A of the second semiconductor memory chip 2B. The bonding wire 19 corresponds in function to the second bonding wire 7. The bonding wire 19 is electrically connected to the third semiconductor memory chip 2C and the fourth semiconductor memory chip 2D which correspond to, for example, a power supply wiring of the first semiconductor memory chip 2A and the second semiconductor memory chip 2B to which the second bonding wire 7 is electrically connected, and thus, the power supply can be enhanced.

Even when a plurality of stacked bodies are provided such as in the semiconductor device 300 in the third embodiment, the resistance and inductance of the wiring can be reduced as in the first embodiment.

The semiconductor device 300 in the third embodiment uses more semiconductor memory chips 2 than the semiconductor device 100 in the first embodiment, and the enhancement of the power supply which is advantageous from a viewpoint of high speed operation can be achieved, and therefore, it is possible to achieve both the high-speed operation and the large capacity operation.

### Fourth Embodiment

The fourth embodiment is a modification example of the semiconductor device 100 in the first embodiment, the semiconductor device 200 in the second embodiment, and the semiconductor device 300 in the third embodiment. FIG. 7 illustrates a schematic cross-sectional view of a semiconductor device 400 in the fourth embodiment. Similarly to the third embodiment, the semiconductor device 400 in the fourth embodiment is different from the semiconductor device 100 in a point that a controller chip 8 is provided at a lower level below the stacked bodies of two semiconductor memory chips 2 a piece on the controller chip 8. Furthermore, the two stacked bodies are stacked one upon the other in an inverted manner. The description of the content common to the first embodiment, the third embodiment, and the fourth embodiment will not be repeated.

In the semiconductor device 300 in the third embodiment, the right and left stacked bodies illustrated in FIG. 6 each with two semiconductor memory chips 2 and provided on the adhesive resin composition 14 so as to face each other at the same height though the stacked body of the third semiconductor memory chip 2C and the fourth semiconductor memory chip 2D is rotated by 180° from the stacked body of the first semiconductor memory chip 2A and the second semiconductor memory chip 2B. However, in the semiconductor device 400 in the fourth embodiment, the stacked body of the third semiconductor memory chip 2C and the fourth semiconductor memory chip 2D is stacked on an edge portion of the stacked body of the first semiconductor memory chip 2A and the second semiconductor memory chip 2B. A form of the semiconductor device 400 is also a modification example of the form of the semiconductor device 200 in the second embodiment.

When the third semiconductor memory chip 2C and the fourth semiconductor memory chips 2D are stacked in the same direction as the second semiconductor memory chips 2B so as to be shifted in the Y direction, the four semiconductor memory chips are stacked in the stacked body. However, from a viewpoint of high-speed operation, it is preferable that the total number of the stacked semiconductor memory chips 2 to be connected by one bonding wire is two. As the number of the stacked semiconductor memory chips 2 increases, the wire length of the bonding wire increases, and the resistance and inductance of the wiring increases, which is not preferable from the viewpoint of high-speed operation, though may be acceptable in some instances.

The semiconductor device 400 in the fourth embodiment uses more semiconductor memory chips 2 than the semiconductor device 200 in the second embodiment, and the enhancement of the power supply which is advantageous in a viewpoint of high speed operation can be achieved, and therefore, it is possible to achieve both the high-speed operation and the large capacity operation.

### Other Embodiments

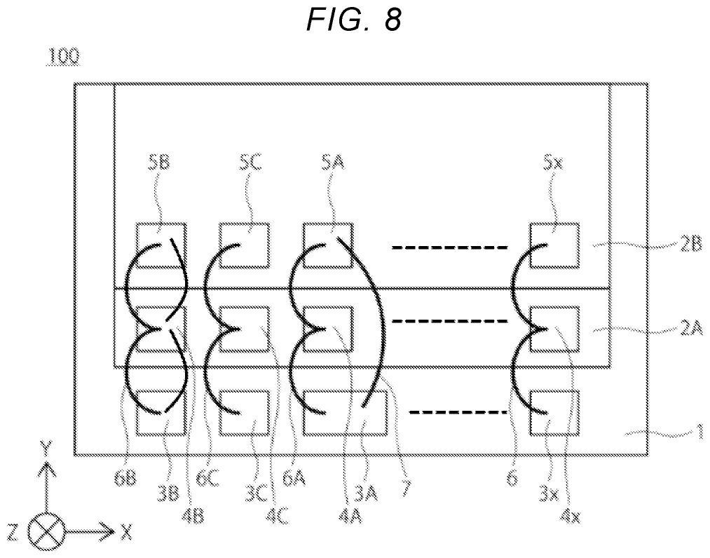

(A) As shown in FIG. 8, two bonding wires for connecting the second terminal 3B and the pad 4B may be provided. Further, two bonding wires for connecting the pads 4B and 5B may be provided. Here, when the first terminal 3A is a power supply terminal, the second terminal 3B is a ground terminal, and when the first terminal 3A is a ground terminal, the second terminal 3B is a power supply terminal. The terminal 3C is a signal terminal. Further, although not shown, a power supply terminal and a ground terminal may be arranged adjacent to all IO terminals on the substrate 1. In the semiconductor chips 2A and 2B, a power supply pad and a ground pad may be arranged adjacent to all the IO pads. All of these power supply pads and ground pads may be provided with two wire bonds for strengthening the power supply, as described in the above embodiments.

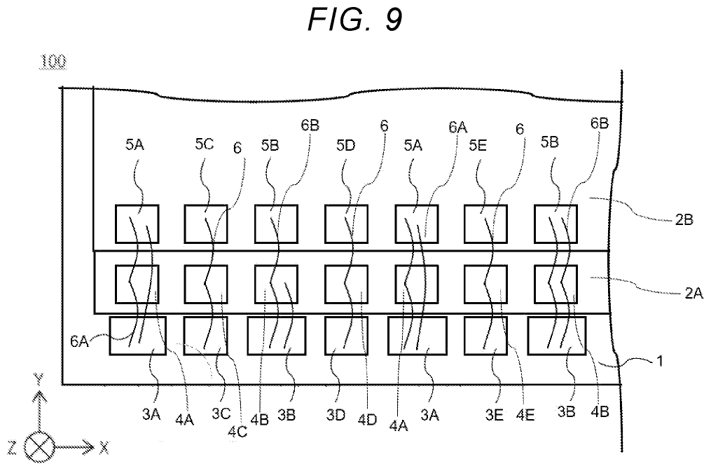

(B) As shown in FIG. 9, there are signal pads 4C, 4D, and 4E for IO input/output of the first semiconductor chip. The power supply pad 4A is arranged adjacent to the IO pads 4C, 4D, and 4E, and the ground pad 4B is arranged adjacent to the IO pads 4C, 4D, and 4E. There are signal pads 5C, 5D, and 5E for IO input/output of the second semiconductor chip. The power supply pad 5A is arranged adjacent to the IO pads 5C, 5D, and 5E, and the ground pad 5B is arranged adjacent to the IO pads 5C, 5D, and 5E. The first terminal 3A is a power supply terminal, the second terminal 3B is a ground terminal, and the IO terminals 3C, 3D, and 3E are IO input/output terminals.

In at least one of the plurality power supply pads, the power supply may be strengthened by bonding wires from the power supply terminals. Further, in at least one of the plurality of ground pads, the ground supply may be strengthened by bonding wires from the ground terminal.

For example, the voltage applied to the pad 5A is strengthened by wire bonding from the first terminal 3A, which is used as a power supply terminal. Since the pad 4B has a second terminal 3B, which is used as a grounding terminal, the voltage is strengthened by wire bonding. However, the power supply of the pads 4A and 5B is not strengthened directly from the board.

That is, it is sufficient that at least one of a plurality of power supply pads adjacent to the IO pad forms a circuit loop between the power supply terminals. It is sufficient that at least one of a plurality of ground pads adjacent to the signal pad forms a circuit loop between the ground terminals.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a substrate having a first terminal;
a first semiconductor memory chip on the substrate and having a first pad;
a second semiconductor memory chip on the first semiconductor memory chip and having a second pad;
a first bonding wire that connects to the first terminal and both the first pad and the second pad; and
a second bonding wire that connects to the first terminal and one of the first pad or the second pad from a coordinate position offset from a coordinate position of the first bonding wire.

2. The semiconductor device according to claim 1, wherein the first bonding wire and the second bonding wire form a circuit loop.

3. The semiconductor device according to claim 1, wherein the first and second pads are both a power supply pad or a ground pad.

4. The semiconductor device according to claim 1, wherein
the substrate has a second terminal and a third terminal,
the first semiconductor memory chip has a third pad and a fourth pad,
the third terminal is between the first terminal and the second terminal and adjacent to at least one of the first and second terminals,
the fourth pad is between the first pad and the third pad and adjacent to at least one of the first and third pads,
a third bonding wire connects to the second terminal and the third pad,
a fourth bonding wire connects to the third terminal and the fourth pad,
the fourth pad is an input/output pad,
the first pad is a power supply pad or ground pad, and
the third pad is the other of the power supply and the ground pad.

5. The semiconductor device according to claim 4, wherein a shape of the fourth bonding wire is different from that of the adjacent first bonding wire and third bonding wire.

6. The semiconductor device according to claim 1, wherein the first pad and the second pad are each a power supply pad.

7. The semiconductor device according to claim 1, wherein the first pad and the second pad are each a ground pad.

8. The semiconductor device according to claim 1, wherein the first semiconductor memory chip and the second semiconductor memory chip having substantially identical circuit designs and the first and second pads have the same function as one another within the respective circuit designs.

9. The semiconductor device according to claim 1, further comprising:
a third semiconductor memory chip on the substrate having a third pad;
a fourth semiconductor memory chip on the third semiconductor memory chip and having a fourth pad;
a third bonding wire that connects to a second terminal on the substrate and both the third pad and the fourth pad; and
a fourth bonding wire that connects to the second terminal and one of the third pad or the fourth pad from a coordinate position offset from a coordinate position of the third bonding wire.

10. The semiconductor device according to claim 9, wherein the third semiconductor memory chip is mounted on the substrate at a position spaced from the first semiconductor memory chip.

11. The semiconductor device according to claim 9, wherein the third semiconductor memory chip is mounted on an upper surface of the second semiconductor memory chip.

12. A semiconductor device, comprising:
a wiring substrate having a plurality of terminals including a first terminal, a second terminal, and a third terminal aligned in a row, the third terminal being between the first and second terminals in the row and adjacent to at least one of the first and second terminals;
a first chip mounted on the wiring substrate and having a plurality of pads on an upper surface thereof, the plurality of pads including a first pad, a second pad, and a third pad aligned in row, the third pad being between the first and second pads in the row and adjacent to at least one of the first and second pads;
a second chip stacked on the upper surface of first chip and having a plurality of pads on an upper surface thereof, the plurality of pads including a fourth pad, a fifth pad, and a sixth pad aligned in row, the sixth pad being between the fourth and fifth pads in the row and adjacent to at least one of the fourth and fifth pads;
a first bonding wire connecting to the first terminal, the first pad, and the fourth pad;
a second bonding wire connecting to the second terminal, the second pad, and the fifth pad;
a third bonding wire connecting to the third terminal, the third pad, and the sixth pad; and
a fourth bonding wire connecting to the second terminal and one of the second pad or the fifth pad but not both from a coordinate position offset along a direction of the row from a coordinate position of the second bonding wire.

13. The semiconductor device according to claim 12, wherein the fourth bonding wire connects to the fifth pad.

14. The semiconductor device according to claim 12, wherein the fourth bonding wire connects to the second pad.

15. The semiconductor device according to claim 12, wherein the second terminal is at a start of the row of the plurality of terminals.

16. The semiconductor device according to claim 12, wherein the first terminal is at a start of the row of the plurality of terminals.

17. The semiconductor device according to claim 12, wherein only the third terminal is between the first and second terminals in the row.

18. The semiconductor device according to claim 12, further comprising:
a fourth terminal, a fifth terminal, and a sixth terminal in the plurality of terminals of the wiring substrate, the fourth terminal, fifth terminal, and the sixth terminal aligned in a row, the sixth terminal being between the fourth and fifth terminals and adjacent to at least one of the fourth and fifth terminals;
a third chip mounted on the wiring substrate and having a plurality of pads on an upper surface thereof, the plurality of pads including a seventh pad, an eighth pad, and ninth pad aligned in a row, the ninth pad being between the seventh and eighth pads in the row and adjacent to at least one of the seventh and eight pads;
a fourth chip stacked on the upper surface of third chip and having a plurality of pads on an upper surface thereof, the plurality of pads including a tenth pad, an eleventh pad, and a twelfth pad aligned in row, the twelfth pad being between the tenth and eleventh pads in the row and adjacent to at least one of the tenth and eleventh pads;
a fifth bonding wire connecting to the fourth terminal, the seventh pad, and the tenth pad;
a sixth bonding wire connecting to the fifth terminal, the eighth pad, and the eleventh pad;
a seventh bonding wire connecting to the sixth terminal, the ninth pad, and the twelfth pad; and
an eighth bonding wire connecting to the fifth terminal and one of the eighth pad or the eleventh pad but not both from a coordinate position offset along a direction of the row from a coordinate position of the sixth bonding wire.

19. The semiconductor device according to claim 18, further comprising:
a controller chip electrically connected to the first, second, third, and fourth chips.

20. The semiconductor device according to claim 12, further comprising:
a fourth terminal, a fifth terminal, and a sixth terminal in the plurality of terminals of the wiring substrate, the fourth terminal, fifth terminal, and the sixth terminal aligned in a row, the sixth terminal being between the fourth and fifth terminals and adjacent to at least one of the fourth and fifth terminals;
a third chip mounted on the second chip and having a plurality of pads on an upper surface thereof, the plurality of pads including a seventh pad, an eighth pad, and ninth pad aligned in a row, the ninth pad being between the seventh and eighth pads in the row and adjacent to at least one of the seventh and eight pads;
a fourth chip stacked on the upper surface of third chip and having a plurality of pads on an upper surface thereof, the plurality of pads including a tenth pad, an eleventh pad, and a twelfth pad aligned in row, the twelfth pad being between the tenth and eleventh pads in the row and adjacent to at least one of the tenth and eleventh pads;
a fifth bonding wire connecting to the fourth terminal, the seventh pad, and the tenth pad;
a sixth bonding wire connecting to the fifth terminal, the eighth pad, and the eleventh pad;
a seventh bonding wire connecting to the sixth terminal, the ninth pad, and the twelfth pad; and
an eighth bonding wire connecting to the fifth terminal and one of the eighth pad or the eleventh pad but not both from a coordinate position offset along a direction of the row from a coordinate position of the sixth bonding wire.
